(19) United States
(12) Patent Application Publication
(10) Pub. No.: US 2008/0014420 A1
(43) Pub. Date: Jan. 17, 2008

(54) Surface treatment for titanium or titanium-alloys

(75) Inventor: Shui Woo Chan, Tsuen Wan (HK)

Correspondence Address: JONES DAY, 555 SOUTH FLOWER STREET FIFTIETH FLOOR, LOS ANGELES, CA, 90071, US

(73) Assignee: Ion Technology (Hong Kong) Limited

(21) Appl. No.: 11/484,332

(22) Filed: Jul. 11, 2006

(51) Int. Cl. B32B 9/00; B32B 7/02; C23C 14/32

(52) U.S. Cl. 428/213; 428/698; 204/192.1; 204/192.32

(57) ABSTRACT

The present invention relates to a process for forming a novel coating on the surface of Titanium (Ti) or Ti-alloy substrates. The layered coating improves, among others, the overall hardness of the surface and leads to a surface that is shinier and more resistant to fingerprints than surfaces obtaining by treatment methods known from the prior art. The present invention also relates to a novel layer sequence for a coating formed on a substrate containing Ti. In one embodiment, the coating includes a transition layer, a hardness layer and a coloring layer. This coating protects the surface and maintains the metallic appearance of

### FIELD

The present invention relates to a process for forming a novel coating on the surface of Titanium (Ti) and/or Ti-alloys or on substrates that comprise Ti, which improves, among others, the overall hardness of the surface and leads to a surface that is shinier and more resistant to fingerprints than surfaces obtained by treatment methods known from the prior art. The present invention also relates to a novel layering sequence for coating a substrate containing Ti comprising a transition layer, a hardness layer and a coloring layer. This coating protects the surface and maintains the metallic appearance of the coated product.

### BACKGROUND

Titanium is a desirable metal to be used in consumer goods as well as in technical products. In particular in alloys, Ti displays extraordinary mechanical strength while having only about a third of the density of stainless steel, i.e. being significantly lighter.

The surface of Ti or Ti-alloys, however, is seen as having some drawbacks that may diminish its appeal: (a) although Ti is structurally strong, Ti is comparatively malleable (“soft”) leading to surfaces that may be easily scratched; (b) the surface of Ti or Ti-alloys is comparatively sensitive to the grease of the human skin and thus sensitive to fingerprints; and (c) even when highly polished, Ti looks comparatively dull (compared to, for example, stainless steel or Platinum).

Partial solutions to these problems are known from the prior art. For example, it is common to apply a thin oil film to a Ti surface to avoid lasting effects of finger prints. Another commonly employed method is to apply a thin layer of a metal or a semi-metal oxide, such as Al2O3, MgO or SiO2, onto the Ti or Ti-alloy surface (see, for example, U.S. Pat. No. 4,906,524 and U.S. Pat. No. 5,091,224). Furthermore, in order to obtain a shiny look, a thin layer of Platinum is sometimes electroplated onto the Ti or Ti-alloy surface.

However, although the above-referenced processes of the prior art may partially render Ti or Ti-alloy surfaces more resistant to scratching and/or fingerprinting and/or may make said surfaces shinier, they are associated with several draw-backs. For example, applying an oil layer on top of the Ti or Ti-alloy surface results in a non-clean surface and in uneven coloring. Such a surface is still easily scratched and will have the dull appearance typical for Ti or Ti-alloys. SiO2 coatings on top of Ti/Ti-alloys typically last only for a short period of time since these types of layers wear off quickly due to mismatch of its constituents Si and Ti.

Titanium nitride (TiN) coatings are also known in the art as suitable coatings for Ti/Ti-alloys to improve the substrate's surface properties (see, for example, U.S. Pat. No. 4,643,952 or U.S. Pat. No. 4,415,421). TiN reflects in a spectrum similar to elemental Gold (Au), i.e. has a golden coloring. In fact, because of its metallic golden color, TiN is used to coat costume jewelry and automotive trim for decorative purposes. TiN films are usually applied by either reactive growth (for example, annealing a piece of titanium in nitrogen) or physical vapor deposition, with a depth of about 3 micrometers. In both methods, pure titanium is sublimated and reacted with nitrogen in a high-energy, vacuum environment.

While thick TiN coatings are generally durable and resist abrasion, they are also brittle and thus prone to cracking and peeling during bending.

There exist several commercially-used variants of TiN that have been developed in the past decade, such as titanium carbon nitride (TiCN) or titanium aluminum nitride (TiAlN), which may be used alone or in alternating layers with TiN. These coatings offer similar corrosion resistance and hardness as TiN coatings, however all have a pronounced coloring ranging from light gray to nearly black, depending on the exact process of application. For many applications, such a coloring or “look” may be unwanted or technically unfavorable. Prior art of the above-described kind can be found, for example, in U.S. Pat. No. 4,643,952 or in an article by J.-H. Jeon et al. (Surface & Coatings Technology 188-189 (2004), page 415-419).

### SUMMARY

Overall, it is an object according to the present invention to provide a process that increases the hardness of the surface of Ti, or of a Ti alloy, and in particular in-creases the resistance of said surface against scratches. Correspondingly, it is an object of the present invention to provide a Ti or Ti-alloy product that has a coating of increased hardness and scratch resistance over a Ti or Ti-alloy product without such a coating or with a different coating.

As another object according to the present invention, the Ti or Ti-alloy surface should be shinier (i.e. of higher gloss) than the surface of coated Ti or Ti-alloy surface known from the prior art. In a further object, the process should result in a coating that does not alter the metallic coloring of the original surface comprising Ti, in particular avoids the appearance of a yellowish golden and/or brownish color. Rather, the coated surface should have the look of a stainless steel or a platinum-type surface.

In yet another object, a process and a product should be provided that makes Ti or Ti-alloy surfaces less susceptible to fingerprints.

These and other objects are solved by a process for coating a Ti or Ti-alloy substrate, or a substrate comprising Ti or Ti-alloy, comprising at least the following steps:

(b) sputtering the surface with metal particles from a metal source, wherein preferably at least some of the metal particles are deposited onto the surface to form an adhesion layer;

(c) depositing Titanium particles from a Ti source or Chromium particles from a Cr source, in the presence of a carbohydrate gas onto the surface as prepared in step (b);

(d) depositing Titanium particles from a Ti source or Chromium particles from a Cr source and, at the same time, Silicon particles from a Si source in the presence of a carbohydrate gas and nitrogen gas onto the surface as prepared in step (c).

These and other objects are also solved by a Ti or Ti-alloy substrate or a substrate comprising Ti or Ti-alloy, having the following sequence of layers deposited on top of the surface of the substrate, as a coating, in the following order:

(C) at least one thin transitional layer comprising TiC or CrC;

(D) at least one hardness layer comprising TiSiCN or TiCrCN, which is thicker than layer (C).

The process according to the present invention may comprise at least the following steps:

(a) optionally cleaning the Ti or Ti-alloy surface in vacuum by sputtering the surface with a noble gas in an electrical field as preferably applied within a vacuum chamber (sputtering chamber);

(b) cleaning a Ti or Ti-alloy surface, optionally as obtained from step (a), by sputtering the surface with metal particles from a metal source; and changing the sputtering conditions so that at least some of the metal particles are deposited onto the surface to form an adhesion layer;

(c) depositing Titanium particles from a Ti source or Chromium particles from a Cr source, in the presence of a carbohydrate gas, preferably inside a sputtering chamber, onto the surface as prepared in step (b);

(d) depositing Titanium particles from a Ti source or Chromium particles from a Cr source simultaneously with Silicon particles from a Si source, in the presence of a carbohydrate gas and nitrogen, preferably inside a sputtering chamber, onto the surface as prepared in step (c).

In the context of the present application, the term “sputtering” refers to any method of accelerating a particle, preferably an ionized particle, preferably in an electrical field as applied in a vacuum, so that it impinges onto a surface, preferably the surface of the substrate that is to be coated. The ionized particles may be created from an inert gas (such as Ar), or from a reactive gas (such as a carbohydrate gas), as well as from a gas that may be reactive under some conditions (such as N2). The ionized particle may also be created from any type of solid substrate, such as a target wire or arc, preferably comprising a metal and/or a semimetal and/or a semiconductor.

In the context of the present invention, “Titanium” (or “Ti”) refers to Titanium metal as sold and used commercially, i.e. potentially comprising typical amounts of additives and/or impurities. However, pure Ti comprising at least 99.8% Ti is preferred. “Titanium alloys” (or “Ti-alloys”) refer to alloys of two or more components, wherein one component is Ti. No restrictions exist with respect to the number, type or nature of the at least one other component. Alloys are preferred in which the addition of Ti increases the mechanical strength over the mechanical strength that the alloy would have in case no Ti were added.

In a preferred embodiment of the present invention, “particles” to be deposited onto a surface are present as (partially) charged particles, i.e. as ions.

After the sequence of steps (a)-(d) or (b)-(d) as described above, the Ti or Ti-alloy substrate preferably has the following sequence of layers as a coating: As an optional transitional layer to increase adhesion of subsequent layers, the Ti or Ti-alloy substrate surface may have a thin layer (B) comprising a metal as optionally deposited in step (b). This layer is an “adhesion” or “seeding” layer. The metal is preferably a transition metal, further preferably selected from Ti, Cr, Mn, Fe, Co, Ni, or Cu. Titanium or Chromium ions are particularly preferred. In a preferred embodiment of the present invention, the thickness of this thin transitional metal layer as deposited ranges from 0.02 to 0.5 μm, preferably from 0.05 to 0.2 μm.

The next layer (or the first layer in case no metal is deposited in step (b)) is a thin transitional layer (C) comprising TiC as deposited in step (c). It also conceivable that Cr is deposited in the presence of a carbohydrate gas thus leading to a CrC layer. Mixtures of TiC and CrC are also conceivable. In either case, the thickness of this thin transitional layer preferably ranges from 0.02 to 0.2 μm, further preferably from 0.05 to 0.1 μm. In case the two thin (B) and (C) layers are used together, i.e. the TiC or CrC on top of the metal layer on top of the Ti or Ti-alloy substrate, it is preferred that these two layers are of the same or of a similar thickness.

The next layer (D) is a “hardness layer” comprising TiSiCN or CrSiCN as deposited in step (d). The thickness of this layer ranges from 0.2 to 5 μm, preferably from 0.5 to 2 μm, further preferably from 0.6 to 1.0 μm. Varying the thickness of this hardness layer in these ranges will not significantly alter the color of the final product. Mixtures of TiSiCN and CrSiCN (optionally with the addition/doping of further metal or semi-metal components) in varying stochiometries are also conceivable.

Optionally, the process according to the present invention also comprises the following steps in addition to the above-describes steps (a)-(d) or (b)-(d):

(e) subsequent to step (d), stopping all inflow of gases and achieving a vacuum;

(f) depositing Cr ions, preferably from an array of at least two arcs, in the presence of a carbohydrate gas, onto the surface as prepared in step (d).

After applying these two additional steps, the coating will have an additional layer (F) on top of the previously described TiSiCN or CrSiCN hardening layer, namely a layer comprising CrC. This layer has the purpose to adjust the “color” (i.e. the reflected wavelength range) of the overall coating. Applying this coloring layer is meant to bring the overall color appearance closer to the appearance of stainless steel. Instead of Cr, other metal ions may be used so long as they adjust the color in the same or in a similar manner. In a preferred embodiment of the present invention, the thickness of this coloring layer (F) ranges from 0.02 to 0.2 μm, preferably from 0.05 to 0.1 μm.

A sequence of layers (B)-(C)-(D)-(F) is shown in FIG. 2 as discussed below

The process steps as described above are preferably performed in a chamber in which a controlled atmosphere and a vacuum can be established, maintained and controlled (“sputtering chamber”).

In a preferred embodiment, the sputtering chamber is warmed up prior to step (a) or prior to step (b), and a vacuum better than 10⁻² Pa, preferably better than 5·10-3 Pa, further preferred better than 10⁻³ Pa, is achieved in the sputtering chamber prior to step (a) or prior to step (b).

### BRIEF DESCRIPTION OF THE DRAWINGS

FIG. 1 shows the schematic side view of a wrist watch (100) with a casing (10), a glass cover (20) and a bezel (30). Casing (10) and bezel (30) represent a substrate comprising Ti that is coated, for example, with a sequence of layers as shown in FIG. 2.

FIG. 2 shows the schematic side view of an exemplary sequence of layers in accordance with the present invention. The substrate (30) may be the bezel of FIG. 1 and comprises Ti. The first layer (B) as deposited onto the substrate (30) is a thin adhesion layer comprising a metal. On top of layer (B), a thin transitional layer (C) comprising TiC or CrC is deposited. On top of said layer (C), a hardness layer (D) comprising TiSiCN or TiCrCN is deposited. Finally, on top of said layer (D), coloring layer (F) comprising CrC is deposited. The relative thickness of the respective layers is shown schematically: In particular, hardness layer (D) is thicker than any of the other layers, namely adhesion layer (B), transitional layer (C) and coloring layer (F).

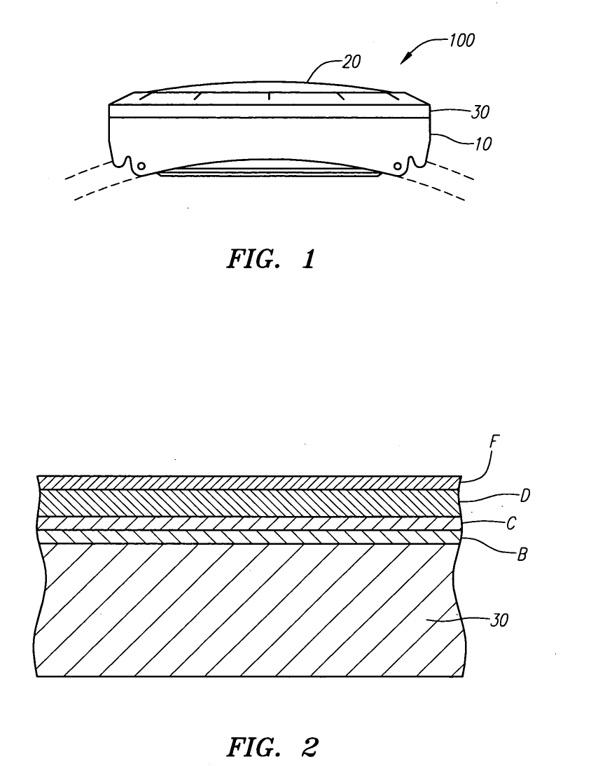

### DETAILED DESCRIPTION OF PREFERRED EMBODIMENTS

Preferred Embodiments in Regard to Step (a):

In a preferred embodiment, the cleaning step (a) is a sputtering step performed with Ar gas, preferably at an Ar pressure of up to 3 Pa. It is further preferred that the sputtering time is more than one minute, preferably more than 5 minutes. Sputtering times of more than 10 minutes are also possible. It is further preferred that the value for the negative bias applied for sputtering is more than −200 V, further preferred more than −500 V.

In a further preferred embodiment, after step (a), the bias and the Ar flow are stopped and a vacuum of at least 10⁻² Pa, preferably of at least 7·10⁻³ Pa, further preferred of at least 5·10⁻³ Pa, further preferred 10⁻³ Pa, is achieved in the sputtering chamber. After this, step (a) is preferably repeated. This sequence of steps may be repeated as often as necessary to achieve a clean Ti or Ti-alloy surface.

Preferred Embodiments in Regard to Step (b):

In a preferred embodiment of the present invention, step (b) has the function to further clean the Ti or Ti-alloy surface since metal particles/ions are heavier than noble gas particles/ions used in step (a), in particular heavier than Ar particles/ions. To achieve this, it is preferred that the bias between substrate and target is positive and that the current and/or the bias is/are selected so that the metal particles/ions do not have sufficient kinetic energy to bond to the substrate surface, i.e. to be deposited. This step of bombarding the substrate surface with metal particles/ions will be labeled as (sub)step (b′) below. It is preferred that a plurality of metal arcs are used as targets, for example six arcs. Preferably, the bias is more than 200 V, further preferred 400 V or more. The preferred current is higher than 20 A, further preferred 60 A or higher.

It is further preferred that step (b), in addition, also has the function to deposit at least parts of the metal particles/ions onto the surface thus creating a thin transitional layer (adhesion layer) that improves the adhesion between the Ti or Ti-alloy substrate surface and subsequently deposited layers, in particular the hardness layer(s); To achieve this, it is preferred that the bias between substrate and target is lowered and that the current and/or the bias is/are selected so that the metal particles/ions do have sufficient kinetic energy to bond to the substrate surface, i.e. to be deposited. It is preferred that a plurality of metal arcs are used as targets, for example six arcs. For example, to achieve (partial) deposition of metal particles, the bias can be lowered from −500 V to −200 V. The preferred current is higher than 30 A, further preferred 70 A or higher. This sub(step) will be labeled as (b″) below.

Overall, step (b) can be seen to comprise two separate steps (b′) and (b″), both being associated with different biases and currents but preferably making use of the same target.

Preferably, the sputtering time for step (b′) and/or step (b″) is at least one minute, further preferred at least 2 minutes, further preferred at least 5 minutes. Among others, film thickness and cohesiveness of the film can be controlled by adjusting the sputtering time.

In a further preferred embodiment, after step (b′) and before step (b″), i.e. before changing bias and/or current, less than 3·10⁻¹ Pa, further preferred less than 1·10⁻¹ Pa of a noble gas, preferably Ar, are flown into the sputtering chamber.

Preferred Embodiments in Regard to Step (c):

In a preferred embodiment, the carbohydrate gas of step (c) is flown into the sputtering chamber at a pressure of no more than 1·10⁻¹ Pa, further preferred at a pressure of no more than 3·10⁻¹ Pa.

In a preferred embodiment of the present invention, the carbohydrate gas is selected from ethane, propane, butane or mixtures thereof.

In a further preferred embodiment, the deposition of the TiC or CrC layer of step (c) is performed for at least 3 minutes, preferably for at least 5 minutes. The sputtering time correlates with the film thickness to be achieved. Therefore, the person skilled in the art will achieve the required film thickness by adjusting, among others, the sputtering time in step (c).

In a further preferred embodiment, the Ti or Cr sputtering target of step (c) is operated at a current of at least 5 A, preferably at least 10 A. In a preferred embodiment of the present invention, a plurality of sputtering targets is used, preferably four or more Ti or Cr sputtering targets.

Preferred Embodiments in Regard to Step (d):

According to step (d), carbohydrate gas and nitrogen gas are used in parallel in the same sputtering chamber. Therein, it is preferred that the carbohydrate gas partial pressure is higher than the nitrogen gas partial pressure. The overall pressure preferably ranges from 3 to 5·10⁻¹ Pa.

In a further preferred embodiment of the present invention, the nitrogen gas of step (d) is flown into the sputtering chamber already containing carbohydrate gas (preferably being at a pressure of no more than 2.9·10⁻¹ Pa) until an overall pressure between 3.1·10⁻¹ Pa and 3.3·10⁻¹ Pa is reached.

In a further preferred embodiment, the deposition of the TiSiCN layer or of the CrSiCN layer of step (d) is performed for at least 10 minutes, preferably for at least 20 minutes, further preferably for at least 25 minutes.

In a further preferred embodiment, the Ti or Cr sputtering target(s) of step (d) are operated at a current of at least 5 A, preferably at least 10 A.

In step (d), the Ti or Cr target(s) is/are used in parallel to a Si target. The overall number of Ti and/or Cr targets is preferably greater than the number of Si targets since more Ti/Cr is to be deposited in the TiSiCN/CrSiCN layer than Si. While Si is present only in comparatively small amounts, its presence is nevertheless essential since it significantly increases the hardness of this layer. A preferred amount of Si in the resulting layer (D) is in the range from 6 to 10 mole %.

The hardness of a Ti or Ti-alloy surface comprising the TiSiCN or CrSiCN layer according to the present invention (as measured, for example, on the Vickers hardness scale) is higher than that of a Ti or Ti-alloy surface having a SiO2 layer or having a TiCN or CrCN layer. The preferred ratio of Ti/Cr targets to Si targets ranges from 2:1 to 6:1, preferably from 4:1 to 5:1. For example, four Ti/Cr targets may be used together with one Si target. Preferred embodiments in regard to step (e):

In a preferred embodiment, a vacuum of less than 10⁻² Pa, preferably of less than 5·10⁻³ Pa, further preferred of less than 10⁻³ Pa is achieved in the sputtering chamber in step (e).

Preferred Embodiments in Regard to Step (f):

In a further preferred embodiment, the carbohydrate gas of step (f) is flown into the sputtering chamber until a pressure of least 10⁻¹ Pa, further preferred at least 3·10⁻¹ Pa, further preferred at least 5·10⁻¹ Pa, is reached.

In a further preferred embodiment, the deposition of the CrC layer of step (f) is performed for at least 4 minutes, preferably for at least 8 minutes, further preferably for at least 10 minutes. The sputtering time will be chosen by the person skilled in the art, so that a desired amount of CrC is formed.

In a further preferred embodiment, the Cr sputtering target(s) of step (f) is/are operated at a current of at least 30 A, preferably at least 60 A, further preferably at least 80 A.

In a preferred embodiment of the present invention, a plurality of Cr arcs are used to deposit CrC onto the layer of step (d). Further preferred, sets of arcs are arranged on opposite sides of the substrate that is to be coated. For example, three arcs each may be arranged one on top of the other (i.e. top arc, mid arc, bottom arc) on two sides of the substrate that is to be coated. The various arcs may be operated at the same or at different currents. For example, three arcs may be used on each side, wherein the top arc is operated at 80 A, while the mid and bottom arcs are operated at a lower current, for example at 70 A. The purpose of this variable arrangement is to be able to deposit a CrC layer (F) of varying thickness onto the previous layer deposited on the substrate (e.g., the layer(s) applied in step (d) in the preferred embodiment). This coloring layer has the function to adjust the final color of the overall coated Ti or Ti-alloy substrate, preferably so that the final color corresponds or comes close to the color appearance of stainless steel.

In a preferred embodiment of the present invention, the color as adjusted is measured with a Konica Minolta Chroma Color Reader CR-300. This allows one to objectively determine the “color”, i.e. the spectrum of reflected light. The “color” is measured according to the CIELAB color model. Preferably, the CIELAB color spectrum of a polished stainless steel surface is measured for reference purposes. Subsequently, the CrC layer as described above is adjusted, until the CIELAB values as measured on stainless steel are sufficiently reproduced, preferably within a 20% range, further preferred within a 10% range.

In a further preferred embodiment, after step (f), the arc power is stopped as well as the carbohydrate gas inflow. In a further preferred embodiment, air is flown into the chamber once the temperature in the chamber has reached a value below 60° C.

Advantages According to the Present Invention:

The process according to the present invention leads to a novel coating comprising a sequence of layers that optically resembles the appearance of steel, thus avoiding a brownish or golden appearance that may not be desirable for Ti or Ti-alloys used for decorative purposes.

Unlike a SiO₂ coating on a Ti or Ti-alloy, varying the thickness of the TiSiCN or CrSiCN hardness layer according to the present invention, in particular increasing the thickness, will not significantly alter the color appearance of the final coating. In particular, the coating according to the present invention does not have a milky yellow appearance if the layer thickness increases (as may be the case for SiO₂ coatings).

Furthermore, in the layer sequence according to the present invention, the adhesion between the TiSiCN or the CrSiCN layer and the Ti or Ti-alloy substrate is particularly strong thus leading to more durable coatings that are more resistant to scratches than other coatings known from the prior art, and/or compared to an uncoated Ti or Ti-alloy surface. Overall, the present coating increases the hardness of the surface, typically to more than 2500 on the Vickers hardness scale, which is higher in comparison to an uncoated Ti or Ti-alloy surface or a Ti or Ti-alloy surface coated with thin films known from the prior art. Further, the inventive coating is not (as) susceptible to fingerprints while providing the above-described shiny metallic appearance.

Use of the Coated Substrate According to the Present Invention:

In principle, no limitations exist with respect to the use of a coated Ti or Ti-alloy substrate according to the present invention. In a preferred embodiment, the coated Ti/Ti-alloy substrates according to the present invention may be used in the watch industry to manufacture watches containing parts made of Ti/Ti-alloy. Furthermore, uses in the field of decorative parts, for example in the automobile industries, are included. The coated substrates according to the present invention may also be used for the manufacture of ball pens, cell phones, camera housings, eye glasses and the like, i.e. generally in the field of (electric) appliances and accessories.

What is claimed is:

1. A process for coating a Ti or Ti-alloy substrate, or a substrate comprising Ti or Ti-alloy, comprising at least the following steps:
(b) sputtering the surface of the substrate with metal particles from a metal source;
(c) depositing Titanium particles from a Ti source or Chromium particles from a Cr source, in the presence of a carbohydrate gas, onto the surface as prepared in step (b);
(d) depositing Titanium particles from a Ti source or Chromium particles from a Cr source and, at the same time, Silicon particles from a Si source, in the presence of a carbohydrate gas and nitrogen gas, onto the surface as prepared in step (c).

2. A process according to claim 1, further comprising the following step, as performed prior to step (b):
(a) cleaning the Ti or Ti-alloy surface in vacuum by sputtering the surface with a noble gas in an electrical field.

3. A process according to claim 1 or 2, wherein at least some of the metal particles of deposition step (b) are deposited onto the surface of the substrate leading to a thin adhesion film.

4. A process according to claim 3, wherein the bias and/or the sputtering current of deposition step (b) is/are adjusted so that the metal particles are deposited, at least in part, onto the substrate.

5. A process according to claim 1 or 2, further comprising the following steps, as performed after step (d):
(e) stopping all inflow of gases of step (d) and achieving a vacuum;
(f) depositing Cr ions, preferably obtained from an array of at least two arcs, in the presence of a carbohydrate gas, onto the surface as prepared in step (d).

6. A process according to claim 1, wherein step (c) is carried out in a sputtering chamber and the carbohydrate gas of step (c) is flown into the sputtering chamber at a pressure of no more than 1·10⁻¹ Pa.

7. A process according to claim 1, wherein the carbohydrate gas is selected from the group consisting of ethane, propane, butane, or a mixture thereof.

8. A process according claim 1, wherein the partial pressure of the carbohydrate gas is higher than the partial pressure of the nitrogen gas in step (d).

9. A process according to claim 1, wherein Ti and/or Cr sources comprise one or more targets and the Si source comprises one or more targets, and wherein the number of Ti and/or Cr targets is greater than the number of Si targets in step (d).

10. A process according to claim 9, wherein TiSiCN is deposited in step (d) and the ratio of Ti targets to Si targets is at least 4:1.

11. A process according to claim 9, wherein CrSiCN is deposited in step (d) and the ratio of Cr targets to Si targets is at least 4:1.

12. A coated substrate comprising a Ti or Ti-alloy substrate having the following sequence of layers deposited on top of it, as a coating, in the following order:
at least one thin transitional layer comprising TiC or CrC;
at least one hardness layer comprising TiSiCN or TiCrCN, which is thicker than the at least one transitional layer.

13. The coated substrate of claim 12, further comprising an adhesion layer consisting essentially of a metal that is interposed between the substrate and the at least one transitional layer and that is thinner than the at least one hardness layer.

14. The coated substrate of claim 12 or 13, further comprising at least one coloring layer comprising CrC that is disposed above the at least one hardness layer and that is thinner than the at least one hardness layer.

15. The coated substrate of claim 13, wherein the metal is a transition metal, preferably selected from Ti, Cr, Mn, Fe, Co, Ni, or Cu.

16. The coated substrate of claim 13, wherein the thickness of the adhesion layer and the at least one transitional layer are each in the range of 0.02 to 0.5 μm as deposited.

17. The coated substrate of claim 12, wherein the thickness of the at least one hardness layer as deposited is in the range of 0.2 to 5 μm.

18. The coated substrate of claim 14, wherein the thickness of the at least one coloring layer as deposited is in the range of 0.02 to 0.2 μm.

19. The coated substrate of claim 18, wherein the color of the coated substrate falls within 20% of the color values measured for the surface of stainless steel as measured in CIELAB units.

20. The coated substrate of claim 12, wherein the overall hardness of the surface of the coated substrate is at least 2000 on the Vickers hardness scale.

21. The coated substrate of claim 12, wherein the Ti or Ti-alloy substrate comprises a component of a watch, a component of an automobile or motorcycle, a component of a consumer electrical appliance, a component of a piece of jewelry, a component of a pair of eyeglasses, a component of a camera, a component of a handheld mobile communication device, or a component of a pen.
